(19) United States
(12) Patent Application Publication
(10) Pub. No.: US 2024/0274461 A1
(43) Pub. Date: Aug. 15, 2024

(54) BONDING TOOL FOR PROVIDING CHIP ON WAFER BOND AND METHODS FOR PERFORMING THE SAME

(71) Applicant: Taiwan Semiconductor Manufacturing Company Limited, Hsinchu (TW)

(72) Inventors: Chia-Yin CHEN, Hsinchu City (TW); I-Chun HSU, Taoyuan County (TW); Yu-Sheng LIN, Taichung City (TW); Yan-Zuo TSAI, Hsinchu City (TW); Yung-Chi LIN, Su-Lin city (TW); Tsang-Jiuh WU, HsinChu (TW); Wen-Chih CHIOU, Miaoli County (TW)

(21) Appl. No.: 18/110,134

(22) Filed: Feb. 15, 2023

(51) Int. Cl. H01L 21/683; H01L 21/67; H01L 23/00

(52) U.S. Cl. CPC H01L 21/6838; H01L 21/67144; H01L 24/80; H01L 24/05; H01L 2224/05647; H01L 2224/80201; H01L 2224/80379; H01L 2224/80895; H01L 2224/80896

(57) ABSTRACT

A die bonding tool having a tool head including a plurality of openings fluidly coupled to a vacuum source to selectively secure a semiconductor die onto the tool head via the application of a suction force. The plurality of openings have non-uniform cross-sectional areas, including one or more first openings having a first cross-sectional area and one or more second openings having a second cross-sectional area that is greater than the first cross-section area. A first minimum offset distance between each of the first openings and any peripheral edge of the tool head is less than a second minimum offset distance between each of the second openings and any peripheral edge of the tool head. The configuration of the openings in the tool head may improve bonding of the semiconductor die to a substrate by inhibiting air becoming trapped between the semiconductor die and the substrate during the bonding process.

### BACKGROUND

The semiconductor industry has grown due to continuous improvements in integration density of various electronic components (e.g., transistors, diodes, resistors, capacitors, etc.). For the most part, these improvements in integration density have come from successive reductions in minimum feature size, which allows more components to be integrated into a given area.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (POP), System on Chip (SoC) or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are vertical cross-sectional views illustrating a process of bonding a semiconductor die to a target substrate using a die bonding tool according to an embodiment of the present disclosure.

FIG. 2A is a vertical cross-sectional view of a die bonding tool according to an embodiment of the present disclosure.

FIG. 2B is a bottom view of the tool head of the die bonding tool of FIG. 2A.

FIG. 3A is a vertical cross-sectional view of a die bonding tool according to another embodiment of the present disclosure.

FIG. 3B is a bottom view of the tool head of the die bonding tool of FIG. 3A.

FIG. 4A is a vertical cross-sectional view of a die bonding tool according to an embodiment of the present disclosure.

FIG. 4B is a bottom view of the tool head of the die bonding tool of FIG. 4A.

FIG. 5A is a vertical cross-sectional view of a die bonding tool according to an embodiment of the present disclosure.

FIG. 5 is a bottom view of the tool head of the die bonding tool of FIG. 5A.

FIGS. 6A-6G are sequential vertical cross-section views illustrating a flip-chip direct bonding process using a die bonding tool according to various embodiments of the present disclosure.

FIG. 7 is a flowchart illustrating a method of bonding a semiconductor die to a substrate according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In various embodiments, bonding of an integrated circuit die to a target substrate, such as a semiconductor wafer, may be accomplished using a flip-chip direct bonding process. In a flip-chip direct bonding process, a semiconductor integrated circuit (IC) die (which may also be referred to as a “chip”) may be picked up using a first tool, flipped over, and placed onto the head of a die bonding tool. The die bonding tool may align the semiconductor IC die over a bonding region of the target substrate and may apply a compressive force to the semiconductor IC die to bond the semiconductor IC die to the bonding region of the target substrate.

The head of the die bonding tool may include a vacuum suction port that may be used to temporarily secure the semiconductor IC die to the head of the die bonding tool via application of a suction force while the die bonding tool aligns the semiconductor IC die over the bonding region of the target substrate. When the semiconductor IC die is properly aligned over and brought into contact with the bonding region of the target substrate, the suction force from the vacuum port may be released causing the semiconductor IC die to be released from the head of the die bonding tool. In many cases, the semiconductor IC dies may include a natural warping or deformation, such as a bow- or cup-shaped deformation. When the semiconductor IC die is released from the head of the die bonding tool, the natural warpage of the semiconductor IC die may result in air becoming trapped between the lower surface of the semiconductor IC die and the upper surface of the bonding region of the target substrate. As the die bonding tool applies a compressive force to the semiconductor IC die during the bonding process, the trapped air may be pushed toward the edges of the semiconductor IC die, which may result in poor or defective bonding between the semiconductor IC die and the target substrate, particularly near the peripheral edges and corner regions of the semiconductor IC die. These defective bonds may reduce overall device yields.

In order to improve the bonding between a semiconductor IC die and a target substrate, various embodiments of the present disclosure are directed to a die bonding tool having a tool head including a plurality of openings (e.g., ports) fluidly coupled to a vacuum source and configured to selectively secure a semiconductor IC die onto the tool head via the application of a suction force on the semiconductor IC die. In various embodiments, the plurality of openings may have non-uniform cross-sectional areas. In some embodiments, one or more first openings of the plurality of openings may have a first cross-sectional area and one or more second openings of the plurality of opening may have a second cross-sectional area that is greater than the first cross-sectional area. In some embodiments, a minimum offset distance between each of the first openings and a peripheral edge of the tool head may be less than a minimum offset distance between each of the second openings and a peripheral edge of the tool head.

Accordingly, the second openings which are further from a peripheral edge of the semiconductor IC die than the first openings may have a larger cross-sectional area and thereby apply a greater suction force over a larger area of the semiconductor IC die. This may help to keep the semiconductor IC die relatively flat against a surface of the tool head while the semiconductor IC die is secured to the tool head. In addition, when the semiconductor IC die is released from the tool head, the non-uniform hole sizes enable the semiconductor IC die to be released gradually, with regions of the semiconductor IC die located closer to the center of the die being initially released from the tool head, and regions of the semiconductor IC die located closer to the peripheral edges of the die being subsequently released from the tool head. This may inhibit the formation of air pockets between the lower surface of the semiconductor IC die and the upper surface of the bonding region of the carrier substrate, which may improve the integrity of the bonding between the semiconductor IC die and the carrier substrate and may provide improved device yields.

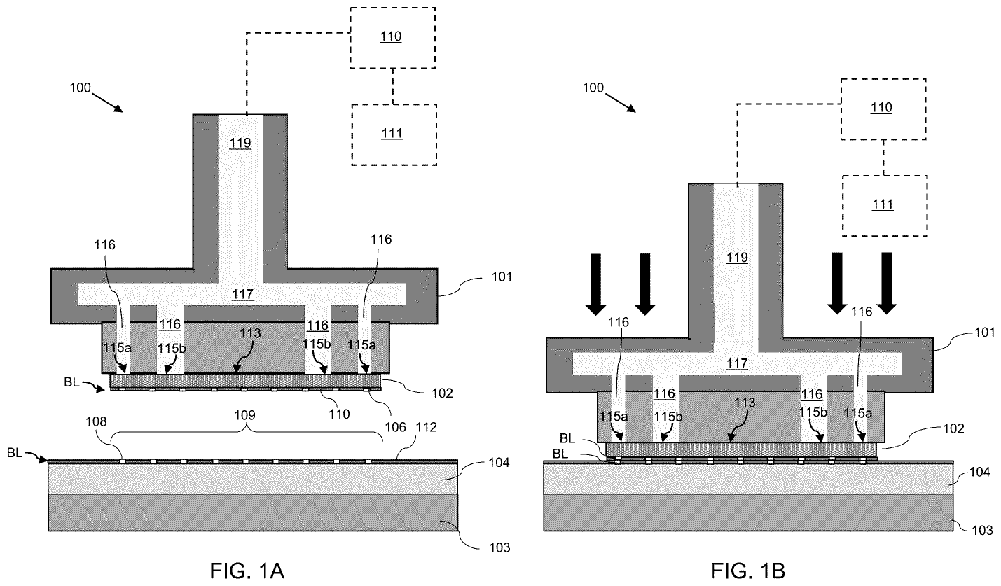

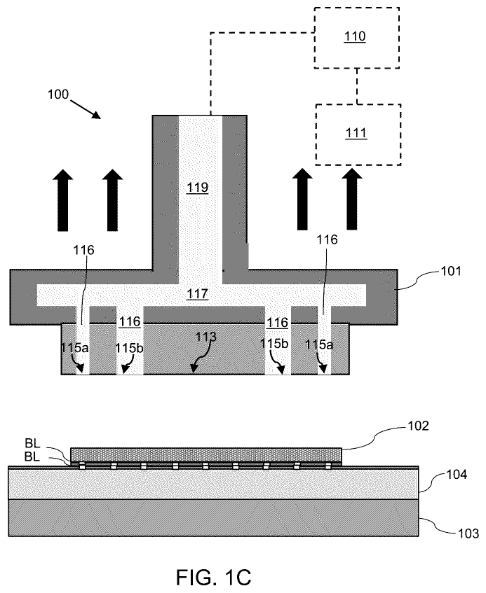

FIG. 1A is a vertical cross-sectional view of a die bonding tool 100 according to various embodiments of the present disclosure. The die bonding tool 100 may include a tool head 101 having a substantially flat lower surface 113. The tool head 101 may also include a plurality of openings 115a, 115b (i.e., ports) in the lower surface 113 of the tool head 101. In some embodiments, a plurality of fluid conduits in the tool head 101 may extend between the openings 115a, 115b in the lower surface 113 of the tool head 101 and an internal plenum 117 of the tool head 101. A fluid conduit 119 may couple the internal plenum 117 of the tool head 101 to a vacuum source 110. The vacuum source 110 may selectively apply a negative pressure within the fluid conduit 119, the plenum 117 and fluid conduits 116 such that a suction force may be generated at each of the openings 115a and 115b. The suction force may be sufficient to secure a semiconductor IC die 102 to the lower surface 113 of the tool head 101.

The semiconductor IC die 102 may include a semiconductor material, such as silicon, having a number of circuit components and elements formed on and/or within the semiconductor material. Semiconductor IC dies 102 are typically fabricated by sequentially depositing insulating or dielectric layers, conductive layers, and semiconductive layers of material over a semiconductor substrate, patterning the various material layers using lithography to form integrated circuits, and separating individual dies from the wafer such as by sawing between the integrated circuits along scribe lines. In some embodiments, the semiconductor IC die 102 may be a system-on-chip (SoC) die. An SoC die may include, for example, an application processor die, a central processing unit die, and/or a graphic processing unit die. In some embodiments, the semiconductor IC die 102 may be a memory die. A memory die may include, for example, a dynamic random access memory (DRAM) die, and/or a high bandwidth memory (HBM) die. Other suitable semiconductor IC dies 102, such as an application-specific integrated circuit (ASIC) die, an analog die, a sensor die, a wireless and radio frequency die, a voltage regulator die, and the like, are within the contemplated scope of disclosure.

In various embodiments, the semiconductor IC die 102 may have a thickness of 775 μm or less, although semiconductor IC dies 102 having greater thicknesses are within the contemplated scope of the disclosure. In some embodiments, the semiconductor IC die 102 may be a relatively thin die having a thickness of about 200 μm or less, such as a thickness between about 30 μm and about 200 μm. Thinner IC dies may be susceptible to deformations such as warping. In various embodiments, the suction force on the semiconductor IC die 102 that is provided by the plurality of openings 115a and 115b in the tool head 101 of the die bonding tool 100 may secure the semiconductor IC die 102 against the lower surface 113 of the tool head 101 in a substantially flat (i.e., non-deformed) position.

A die bonding tool 100 according to various embodiments may be used to bond a semiconductor IC die 102 to a target substrate 104. FIGS. 1A-1C are sequential vertical cross-sectional views illustrating a process of bonding a semiconductor IC die 102 to a target substrate 104 using a die bonding tool 100 according to various embodiments of the present disclosure. Referring again to FIG. 1A, the tool head 101 having the semiconductor IC die 102 secured thereto may be aligned over a bonding region 109 of a target substrate 104. In some embodiments, the target substrate 104 may be a semiconductor material substrate (i.e., a semiconductor wafer). The semiconductor material substrate may have one or more integrated circuits formed on or in the substrate 104. Other suitable target substrates 104, such as glass, ceramic and/or organic material substrates, are within the contemplated scope of disclosure. The target substrate 104 may be located on a lower support member 103, such as a wafer chuck.

The die bonding tool 100 may include a system controller 111, which may be central processing unit (CPU), that may be operatively coupled to the vacuum source 110 and to an actuator system (not shown in FIGS. 1A-1C) configured to move the tool head 101 along one or more horizontal directions with respect to the lower support member 103 in order to align the semiconductor IC die 102 over the bonding region 109 of the target substrate 104. In some embodiments, the lower support member 103 and the target substrate 104 thereon may remain stationary, and the tool head 101 may be moved to position the semiconductor IC die 102 over the bonding region 109. Alternatively, or in addition, the lower support member 103 may be moved to align the semiconductor IC die 102 over the bonding region 109 of the target substrate 104.

Referring to FIG. 1B, the tool head 101 may be configured to move vertically downward to thereby bring the semiconductor IC die 102 into contact with the bonding region 109 of the target substrate 104. As the semiconductor IC die 102 is brought into contact with the bonding region 109 of the target substrate 104, the die bonding tool 100 may release the negative pressure within the fluid conduit 119, the plenum 117 and the fluid conduits 116 (e.g., by turning off/disconnecting the vacuum source 110 and/or providing an ambient or positive pressure within the fluid conduit 119, the plenum 117 and the fluid conduits 116), thereby causing the semiconductor IC die 102 to be released from the lower surface 113 of the tool head 101. The tool head 101 may then apply a compressive force (indicated by the arrows in FIG. 1B) to the upper surface of the semiconductor IC die 102 to facilitate bonding of the semiconductor IC die 102 to the bonding region 109 of the target substrate 104.

In various embodiments, the semiconductor IC die 102 may be bonded to the target substrate 104 using a direct bonding technique, such as a metal-metal (M-M) and dielectric-dielectric (D-D) bonding technique. In some embodiments, the semiconductor IC die 102 may include a bonding layer BL over the lower surface of the semiconductor IC die 102 including plurality of bonding pads 106 composed of a metallic material (e.g., copper) embedded in a dielectric material matrix 112. The target substrate 104 may similarly include a bonding layer BL over the upper surface of the target substrate 104 including a plurality of bonding pads 108 embedded in a dielectric material matrix 112. In various embodiments, the bonding layer(s) of the semiconductor IC die 102 and/or the target substrate 104 may optionally be pre-treated to promote surface activation (e.g., using a plasma treatment process). The lower surface of the semiconductor IC die 102 and the upper surface of the target substrate 104 may contact each other such that the bonding pads 106 of the bonding layer BL of the semiconductor IC die 102 contact corresponding bonding pads 108 of the bonding layer BL of the target substrate 104. The compressive force applied by the tool head 101 of the die bonding tool 100 may facilitate bonding of the bonding layer BL of the semiconductor IC die 102 and the bonding layer BL of the target substrate 104. In some embodiments, the bonding may be performed at room temperature (e.g., ˜20° C.). The target substrate 104 and the semiconductor IC die 102 bonded thereto may optionally be subjected to a subsequent annealing process at elevated temperature to strengthen the bond between the target substrate 104 and the semiconductor IC die 102.

It will be understood that other bonding processes may be used to bond the semiconductor IC die 102 to the target substrate 104. For example, a thermocompression bonding (TCB) process may be utilized to bond metallic structures (e.g., metal bumps, pillars and/or bonding pads) on the lower surface of the semiconductor IC die 102 to corresponding metallic structures (e.g., metal bumps, pillars and/or bonding pads) on the upper surface of the target substrate 104. The tool head 101 of the die bonding tool 100 may apply a compressive force to the semiconductor IC die 102 while the semiconductor IC die 102 and the target substrate 104 are heated. In some embodiments, the semiconductor IC die 102 and the target substrate 104 may be heated by a heating mechanism (not shown) located on the die bonding tool 100. With the applied pressure and the elevated temperature, surface portions of the metallic structures of the semiconductor IC die 102 and the metallic structures of the target substrate 104 may inter-diffuse, so that bonds may be formed therebetween. In some embodiments, the bonding between the semiconductor IC die 102 and the target substrate 104 may be performed without the use of solder material. In other embodiments, a solder material may be used to bond bonding structures of the semiconductor IC die 102 to corresponding bonding structures of the target substrate 104.

Referring to FIG. 1C, following the bonding of the semiconductor IC die 102 to the target substrate 104, the tool head 101 may move vertically upward (as indicated by the arrows) away from the upper surface of the semiconductor IC die 102.

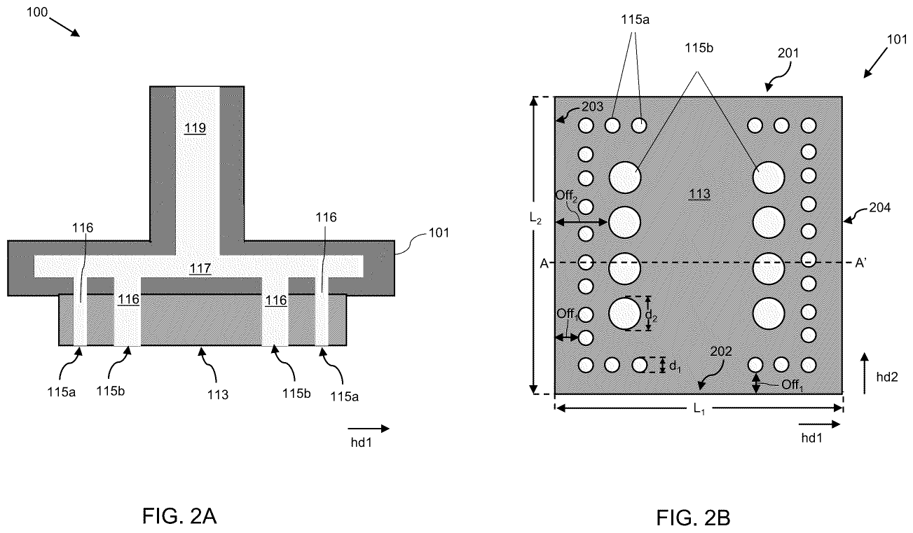

FIG. 2A is a vertical cross-sectional view of a die bonding tool 100 according to an embodiment of the present disclosure. FIG. 2B is a bottom view of the tool head 101 of the die bonding tool 100 of FIG. 2A. The cross-sectional view of FIG. 2A is taken along line A-A′ in FIG. 2A.

Referring to FIGS. 2A and 2B, in various embodiments, the lower surface 113 of the tool head 101 may have a plurality of openings 115a, 115b having non-uniform cross-section areas. In the embodiment shown in FIGS. 2A and 2B, at least one first opening 115a in the lower surface 113 of the tool head 101 may have a first cross-section area (i.e., within a plane parallel to the first horizontal direction hd1 and the second horizontal direction hd2) and at least one second opening 115b in the lower surface 113 of the tool head 101 may have a second cross-section area. The first cross-section area of the at least one first opening 115a may be less than the second cross-section area of the at least one second opening 115b. In some embodiments, the cross-section area of the at least one second opening 115b may be at least two (2) times, such as between about 2.25 and about 12.25 times, larger than the cross-section area of the at least one first opening 115a.

In the embodiment shown in FIGS. 2A and 2B, the lower surface 113 of the tool head 101 includes a plurality of first openings 115a, each having a first cross-section area, and a plurality of second openings 115b, each having a second cross-section area that is greater than the first cross-section area. In this embodiment, both the first openings 115a and the second openings 115b have a circular cross-section shape, although it will be understood that the first openings 115a and/or the second openings 115b may have different shapes, such as a rectangular shape, a triangular shape, an oval shape, an irregular shape, etc. In some embodiments, the first openings 115a may have a dimension (e.g., diameter d₁ in FIG. 2B) along the first horizontal direction hd1 and/or the second horizontal direction hd2 that is between about 0.1 mm and about 0.5 mm. The second openings 115b may have a dimension (e.g., diameter d₂ in FIG. 2B) along the first horizontal direction hd1 and/or the second horizontal direction hd2 that is at least 1.5 times, such as between 1.5 and 3.5 times, larger than the corresponding dimension of the first openings 115a. Accordingly, in the embodiment shown in FIGS. 2A and 2B, the second openings 115b may have a diameter d2 that is between about 0.15 mm and about 1.75 mm.

Referring to FIG. 2B, the lower surface 113 of the tool head 101 may have a rectangular or square shape including a first peripheral edge 201 and a second peripheral edge 202 extending parallel to one another along a first horizontal direction (i.e., hd2 in FIG. 2B), and a third peripheral edge 203 and a fourth peripheral edge 204 extending parallel to one another along a second horizontal direction (i.e., hd2 in FIG. 2B). Other suitable shapes for lower surface 113 of the tool head 101 are within the contemplated scope of disclosure. In some embodiments, the shape of the lower surface 113 of the tool head 101 may correspond to the shape of the semiconductor IC die(s) 102 that are secured against the lower surface 113 of the tool head 101 during a die bonding process as described above. The lower surface 113 of the tool head 101 may have a first length dimension L₁ along the first horizontal direction hd1, and a second length dimension L₂ along the second horizontal direction hd2. The length dimensions L₁ and L₂ of the lower surface 113 of the tool head 101 may be greater than or lesser than the corresponding length dimensions of the semiconductor IC die(s) 102. In some embodiments, the length dimensions L₁ and L₂ of the lower surface 113 of the tool head 101 may be within ±10% of the corresponding length dimensions of the semiconductor IC die(s) 102 that are secured to the tool head 101.

Referring again to FIG. 2B, each of the first openings 115a and the second openings 115b may have a minimum offset distance between the opening 115a, 115band any peripheral edge 201, 202, 203 and 204 of the lower surface 113 of the tool head 101. The minimum offset distance may be defined as the shortest distance between the respective opening 115a, 115b and any peripheral edge 201, 202, 203 and 204 of the lower surface 113 of the tool head 101. Thus, while each of the openings may have an offset distance relative to each of the peripheral edges of the lower surface 113 of the tool head 101, the respective minimum offset distance (e.g., Off₁, Off₂) is the minimum value of all possible offset distances. As illustrated in FIG. 2B, each of the first openings 115a may have a minimum offset distance Off₁ and each of the second openings 115b may have a minimum offset distance Off₂. In various embodiments, the minimum offset distances Off₁ of each of the first openings 115a may be less than the minimum offset distances Off₂ of each of the second openings 115b. Thus, as shown in FIG. 2B, the first openings 115a may be located closer to the periphery of the lower surface 113 of the tool head 101, and the second openings 115b may be located closer to the center of the lower surface 113 of the tool head 101.

In the embodiment shown in FIGS. 2A and 2B, the second openings 115b are arranged in a pair of columns (may also be referred to as “rows”) of second openings 115b extending along the second horizontal direction hd2. Each of the columns of second openings 115b is laterally offset from the center of the lower surface 113 of the tool head 101 along the first horizontal direction hd1. The first openings 115a are arranged two groups of first openings 115a, where each group of first openings 115a is arranged in a “U”-shaped pattern that surrounds a respective column of second openings 115b on three sides of the column such that a minimum offset distance Off₁ of each of the first openings 115a is less than the minimum offset distances Off₂ of each of the second openings 115b. Numerous variations in the configurations of the first openings 115a and the second openings 115b are within the contemplated scope of disclosure, several of which are described in further detail below.

In various embodiments, the second openings 115b located closer to the center of the lower surface 113 of the tool head 101 may provide a relatively greater suction force near the central region of the semiconductor IC die 102 due to the relatively larger second cross-section area of the second openings 115b as compared to the first cross-section area of the first openings 115a. This may help to maintain the semiconductor IC die 102 in a relatively flat position against the lower surface 113 of the tool head 101 prior to semiconductor IC die 102 being released from the tool head 101. In addition, the arrangement of the openings 115a and 115b in the lower surface 113 of the tool head 101 such that the larger second openings 115b are located closer to the center of the lower surface 113 of the tool head 101 while the smaller first openings 115a are located closer to the peripheral edge(s) 201, 202, 203 and 204 of the lower surface 113 may facilitate a gradual release of the semiconductor IC die 102 from the tool head 101. In particular, regions of the semiconductor IC die 102 underlying the larger second openings 115b and closer to the center of the semiconductor IC die 102 may be released from the tool head 101 prior to the release of peripheral regions of the semiconductor IC die 102 underlying the smaller first openings 115a. This gradual release of the semiconductor IC die 102 from a more central region of the die to the periphery of the semiconductor IC die 102 may prevent air from becoming trapped between the lower surface of the semiconductor IC die 102 and the upper surface of the carrier substrate 104, which may improve the integrity of the bonding between the semiconductor IC die 102 and the carrier substrate 104 and thereby provide improved device yields. Thus, by providing the larger openings 115b interior to the smaller openings 115a, upon release of suction force, interior portions of the semiconductor IC die 102 may contact the upper surface of the carrier substrate 104 prior to or simultaneous with exterior portions of the semiconductor IC die 102 contacting the semiconductor IC die 102, thus enabling air located between the lower surface of the semiconductor IC die 102 and the upper surface of the carrier substrate 104 to escape out along the peripheral edges and corners of the semiconductor IC die 102 without becoming trapped.

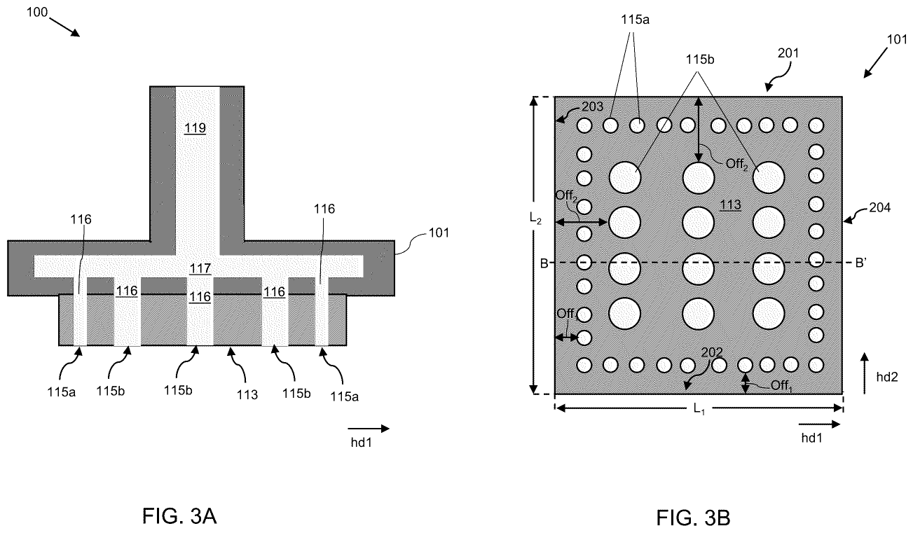

FIG. 3A is a is a vertical cross-sectional view of a die bonding tool 100 according to another embodiment of the present disclosure. FIG. 3B is a bottom view of the tool head 101 of the die bonding tool 100 of FIG. 3A. The cross-sectional view of FIG. 3A is taken along line B-B′ in FIG. 3A.

Referring to FIGS. 3A and 3B, the tool head 101 of the die bonding tool 100 includes a lower surface 113 including plurality of first openings 115a having a first cross-section area and a plurality of second openings 115a having a second cross-section area, where the second cross-section area is greater than the first cross-section area. In the embodiment shown in FIGS. 3A and 3B, the plurality of second openings 115b are arranged in three columns of second openings 115b, where each column extends along the second horizontal direction hd2. A central column of second openings 115b extends through the center of the lower surface 113 of the tool head, and a pair of outer columns of second openings 115b on opposite sides of the central column of second openings 115b. The plurality of first openings 115a extend around the columns of second openings 115b on four sides of the columns of second openings 115b. The plurality of first openings 115a may be arranged in a square- or rectangular-shaped configuration as shown in FIG. 3B, although it will be understood that the plurality of first openings 115a may be arranged in other configurations, such as a circular- or oval-shaped configuration. As in the embodiment described above with reference to FIGS. 2A and 2B, the minimum offset distance Off₁ of each of the first openings 115a is less than the minimum offset distances Off₂ of each of the second openings 115b in the embodiment shown in FIGS. 3A and 3B.

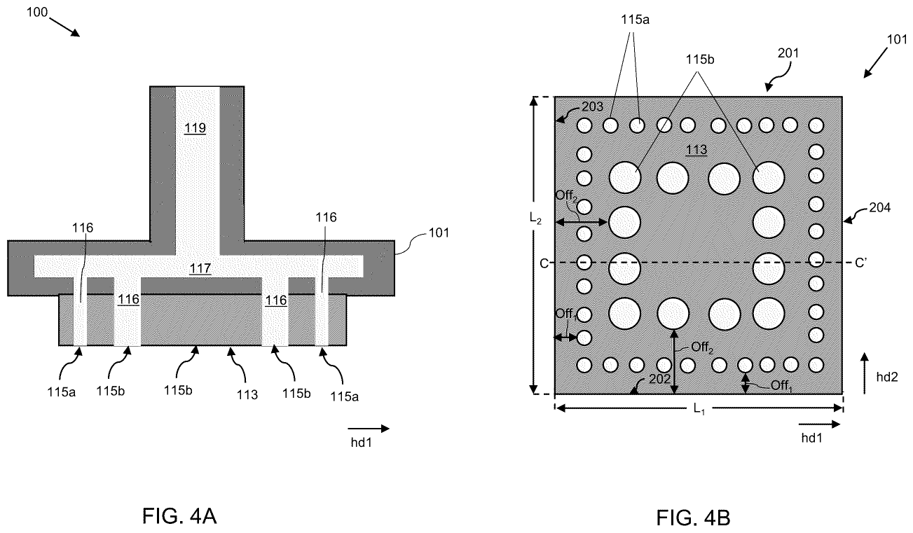

FIG. 4A is a vertical cross-sectional view of a die bonding tool 100 according to another embodiment of the present disclosure. FIG. 4B is a bottom view of the tool head 101 of the die bonding tool 100 of FIG. 4A. The cross-sectional view of FIG. 4A is taken along line C-C′ in FIG. 4A.

Referring to FIGS. 4A and 4B, the tool head 101 of the die bonding tool 100 includes a lower surface 113 including a plurality of first openings 115a having a first cross-section area and a plurality of second openings 115a having a second cross-section area, where the second cross-section area is greater than the first cross-section area. The embodiment shown in FIGS. 4A and 4B is similar to the embodiment shown in FIGS. 3A and 3B with the exception that in the embodiment of FIGS. 4A and 4B, the plurality of second openings 115b are arranged in a square- or rectangular-shaped configuration around the center of the lower surface 113 of the tool head 101. The plurality of first openings 115a are arranged in a square- or rectangular-shaped configuration around the plurality of second openings 115b. It will be understood that the plurality of first openings 115a and/or the plurality of second openings 115b may be arranged in alternative configurations, such as a circular- or oval-shaped configuration. The plurality of second openings 115b may surround the center of the lower surface 113 on four sides, and the plurality of first openings 115a may surround the plurality of second openings 115b on four sides (or around a circumference in embodiments in which the plurality of second openings 115b are arranged in a circular- or oval-shaped configuration). The minimum first offset distance Off₁ of each of the first openings 115a is less than the minimum second offset distances Off₂ of each of the second openings 115b in the embodiment shown in FIGS. 4A and 4B.

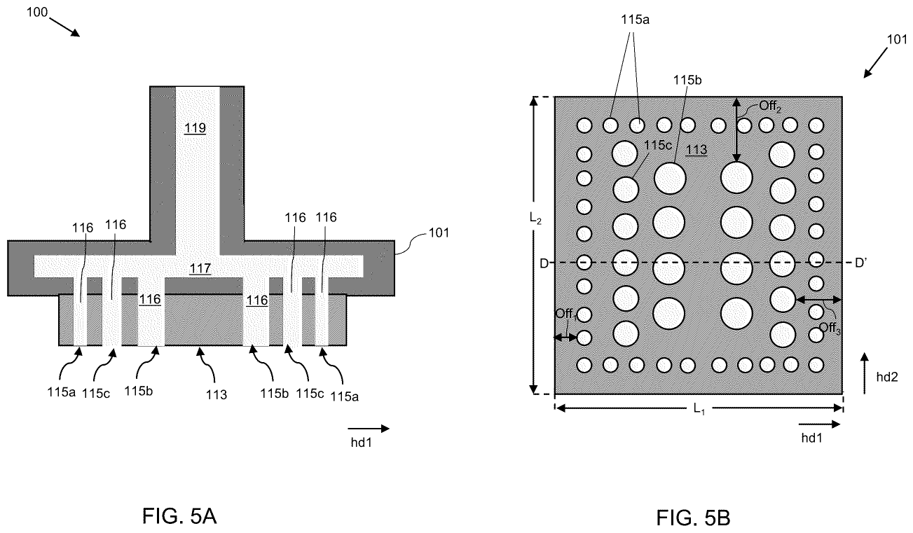

Although the various embodiments shown in FIGS. 1A-4B have included die bonding tools 100 having a tool head 101 with a lower surface 113 that includes openings having two different sizes, it will be understood that various embodiments may include a tool head 101 with a lower surface 113 that includes openings having more than two different sizes, such as three different sizes, four different sizes, etc. FIGS. 5A and 5B illustrate an embodiment of a die bonding tool 100 having a tool head 101 with a lower surface 113 that includes openings 115a, 115b and 115c having three different sizes. FIG. 5A is a vertical cross-sectional view of the die bonding tool 100, and FIG. 5B is a bottom view of the tool head 101 of the die bonding tool 100 of FIG. 4A. The cross-sectional view of FIG. 5A is taken along line D-D′ in FIG. 5A.

Referring to FIGS. 5A and 5B, at least one first opening 115a in the lower surface 113 of the tool head 101 may have a first cross-section area, at least one second opening 115b in the lower surface 113 of the tool head 101 may have a second cross-section area, and at least one third opening 115c in the lower surface 113 of the tool head 101 may have a third cross-section area. The first cross-section area of the at least one first opening 115a may be less than the second cross-section area of the at least one second opening 115b. The third cross-section area of the at least one third opening 115c may have a cross-section area that is greater than the first cross-section area, and less than the second cross section area.

In various embodiments, the lower surface 113 of the tool head 101 may include a plurality of first openings 115a, a plurality of second openings 115b and a plurality of third openings 115c. The plurality of first openings 115a and the plurality of second openings 115b may be arranged such that the minimum first offset distance Off₁ of each of the first openings 115a is less than the minimum second offset distances Off₂ of each of the second openings 115b. In some embodiments, the plurality of third openings 115c may be arranged such that the minimum third offset distance Off₃ of each of the third openings 115c is less than the minimum second offset distances Off₂of each of the second openings 115b and greater than the minimum first offset distances Off₁ of each of the first openings 115a. In the embodiment shown in FIGS. 5A and 5B, the second openings 115b are arranged in a pair of columns of second openings 115bextending along the second horizontal direction hd2 (as in the embodiment of FIGS. 2A and 2B), the first openings 115a extend around the periphery of the lower surface 113 (as in the embodiments of FIGS. 3A-3B and 4A-4B), and the third openings 115c are arranged in a pair of columns of third openings 115c extending along the second horizontal direction hd2 between a respective column of second openings 115b and the first openings 115a. It will be understood that numerous variations in the configuration of the first openings 115a, the second openings 115b and the third openings 115c are within the contemplated scope of disclosure. In other embodiments, the openings in the lower surface 113 of the tool head 101 may have more than three different sizes. In general, the openings may be arranged such that the smaller sized holes are located more proximate to the peripheral edges 201, 202, 203 and 204, with increasing hole size towards the center of the lower surface 113 of the tool head 101.

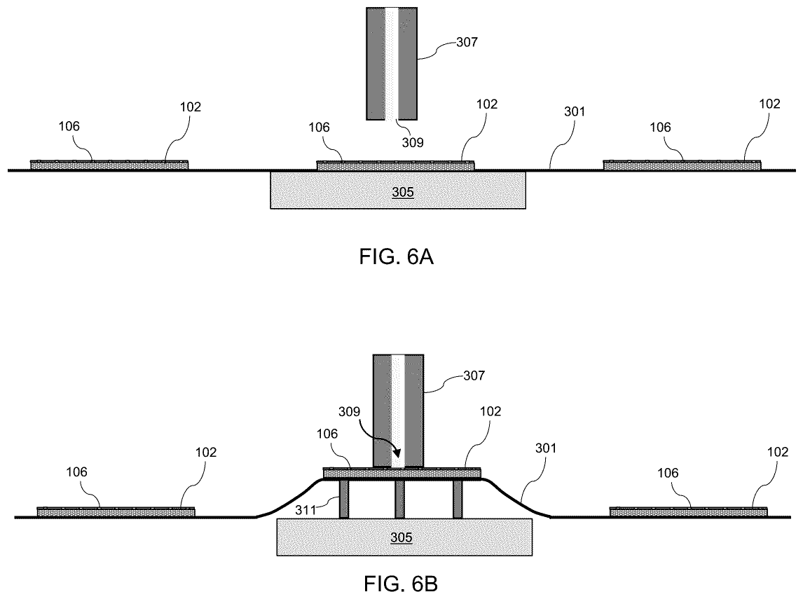

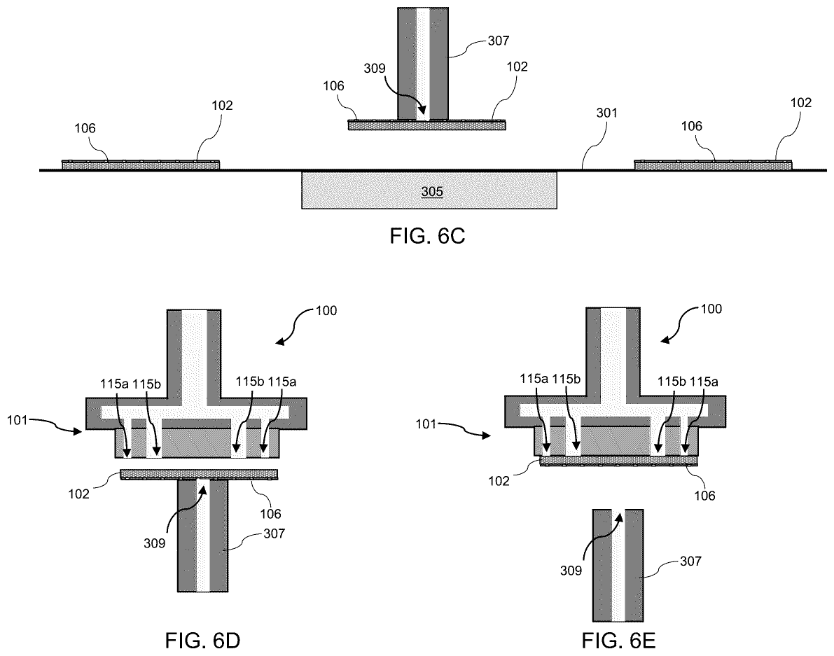

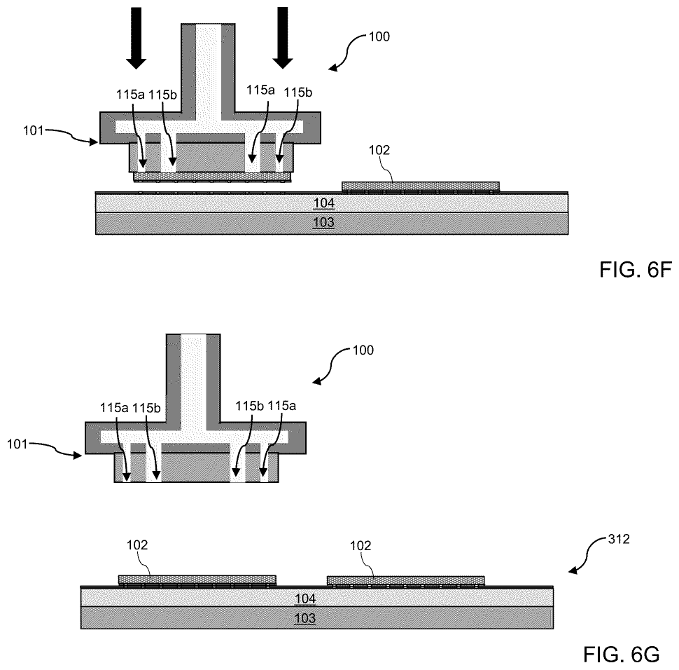

FIGS. 6A-6G are sequential vertical cross-section views illustrating a flip-chip direct bonding process using a die bonding tool 100 according to various embodiments of the present disclosure. Referring to FIG. 6A, a plurality of semiconductor IC dies 102 may be provided on a suitable support element 301, which may be a flexible support, such as a dicing tape supported by a tape frame. A portion of the support element 301 containing a selected semiconductor IC die 102 may be aligned over an ejector apparatus 305. A flip tool 307 that includes a suction port 309 may be positioned over the upper surface of the selected semiconductor IC die 102. The semiconductor IC dies 102 may include bonding structures 106 (e.g., bonding pads, metal bumps, metal pillars, etc.) on the upper surfaces of the semiconductor IC dies 102.

Referring to FIG. 6B, the ejector apparatus 305 may extend pins 311 from an upper surface of the ejector apparatus 305 to lift a portion of the support element 301 and the selected semiconductor IC die 102 such that the upper surface of the selected semiconductor IC die 102 contacts the suction port 309 of the flip tool 307. The suction port 309 may apply a suction force to the upper surface of the selected semiconductor IC die 102 to secure the selected semiconductor IC die 102 to the flip tool 307. Referring to FIG. 6C, the ejector apparatus 305 may retract the pins 311 to cause the support element 301 to separate from the lower surface of the selected semiconductor IC die 102, leaving the selected semiconductor IC die 102 secured to the flip tool 307.

Referring to FIG. 6D, the flip tool 307 may invert (i.e., flip over) the selected semiconductor die 102 that is secured to the flip tool 307 via the suction port 309 such that the bonding structures 106 on the semiconductor IC die 102 are located on the lower surface of the semiconductor IC die 102. Referring to FIGS. 6D and 6E, the upper surface of the semiconductor IC die 102 may be brought into contact with a tool head 101 of an above-described die bonding tool 100. The tool head 101 of the die bonding tool 100 may include a plurality of openings 115a, 115b configured to apply a suction force on the semiconductor IC die 102 as described above to secure the semiconductor IC die 102 to the tool head 101. The openings 115a, 115b may include at least one first opening 115a having a first cross-section area and at least one second opening 115b having a second cross-section area that is greater than the first cross-section area. A minimum first offset distance between the at least one first opening 115a and a periphery of the semiconductor IC die 102 may be less than a minimum second offset distance between the at least one second opening 115b and a periphery of the semiconductor IC die 102, as shown in FIG. 6D. The suction force that is applied by suction port 309 of the flip tool 307 may be released and the flip tool 307 may be separated from the semiconductor IC die 102 as shown in FIG. 6E.

Referring to FIGS. 6F and 6G, the die bonding tool 100 may then be used to bond the semiconductor IC die 102 to a target substrate 104, such as a semiconductor wafer, as described above with reference to FIGS. 1A-1C. One or more additional semiconductor IC dies 102 may also be bonded to the target substrate 104. In various embodiments, the target substrate 104 having one or more semiconductor IC dies 102 bonded thereto may be a chip-on-wafer structure 312. The chip-on-wafer structure 312 may be subjected to further processing steps, such as dicing and/or packaging steps, to provide one or more semiconductor packages.

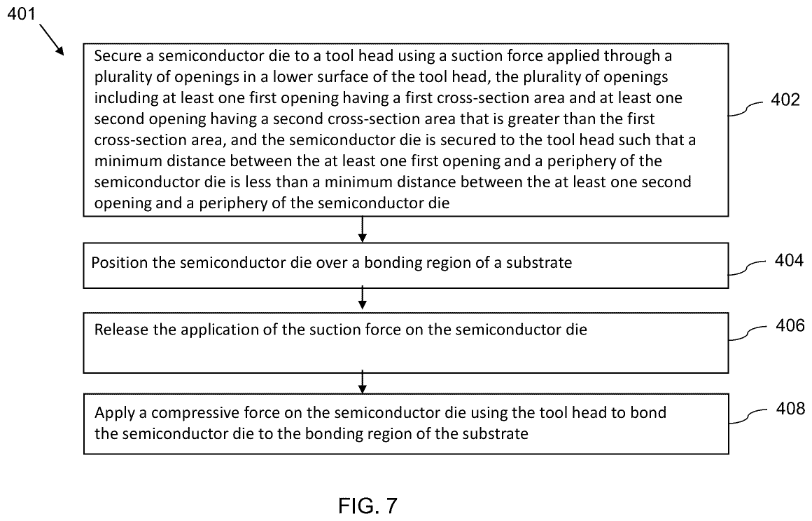

FIG. 7 is a flowchart illustrating a method 401 of bonding a semiconductor die to a substrate according to an embodiment of the present disclosure. Referring to FIGS. 1A, 6D, 6E and 7, in step 402 of method 401, a semiconductor die 102 may be secured to a tool head 101 using a suction force applied through a plurality of openings 115a, 115b in a lower surface 113 of the tool head 101, the plurality of openings 115a, 115b including at least one first opening 115a having a first cross-section area and at least one second opening 115b having a second cross-section area that is greater than the first cross-section area, and the semiconductor die 102 is secured to the tool head 101 such that a minimum first offset distance between the at least one first opening 115a and a periphery of the semiconductor die 102 is less than a minimum second offset distance between the at least one second opening 115b and a periphery of the semiconductor die 102.

Referring to FIGS. 1A, 6F and 7, in step 404 of method 401, the semiconductor die 102 may be positioned over a bonding region 109 of a substrate 104. Referring to FIGS. 1B and 7, in step 406 of method 401, the application of the suction force on the semiconductor die 102 may be released. Referring to FIGS. 1B, 1C, 6F, 6G and 7, a compressive force may be applied to the semiconductor die 102 using the tool head 101 to bond the semiconductor die 102 to the bonding region 109 of the substrate 104 in step 408.

Referring to all drawings and according to various embodiments of the present disclosure, a die bonding tool 100 includes a tool head 101 having a lower surface 113 having a plurality of openings 115a, 115b therein, and a vacuum source 110 fluidly coupled to the plurality of openings 115a, 115b in the lower surface 113 of the tool head 101 and configured to selectively generate a suction force at each of the plurality of openings 115a, 115b to temporarily secure a semiconductor die 102 against the lower surface 113 of the tool head 101, where the tool head 101 is configured to apply a compressive force on the semiconductor die 102 to bond the semiconductor die 102 to a substrate 104, and the plurality of openings 115a, 115b in the lower surface 113 of the tool head 101 include at least one first opening 115a having a first cross-section area and a first minimum offset distance Off₁ between the at least one first opening 115a and any peripheral edge 201, 202, 203, 204 of the lower surface of the tool head 113, at least one second opening 115b having a second cross-section area that is greater than the first cross-section area, and a second minimum offset distance Off₂ between the at least one second opening 115b and any peripheral edge 201, 202, 203, 204 of the lower surface 113 of the tool head 101 that is greater than the first minimum offset distance Off₁.

In one embodiment, the plurality of openings 115a, 115b in the lower surface 113 of the tool head 101 include a plurality of first openings 115a having the first cross-section area and a plurality of second openings 115b having the second cross-section area, wherein the first minimum offset distance Off₁ between one of the plurality of first openings 115a and any peripheral edge 201, 202, 203, 204 of the lower surface 113 of the tool head 101 is less than the second minimum offset distance Off₂ between one of the plurality of second openings 115b and any peripheral edge 201, 202, 203, 204 of the lower surface 113 of the tool head 101.

In another embodiment, the plurality of second openings 115b are arranged in a first column of second openings 115b and a second column of second openings 115b located on opposite sides of a center of the lower surface 113 of the tool head 101, and the plurality of first openings 115a are disposed between the first column of second openings 115b and a peripheral edge 201, 202, 203, 204 of the lower surface 113 of the tool head 101 on three sides of the first column of second openings 115b, and wherein the plurality of first openings 115a are disposed between the second column of second openings 115b and a peripheral edge 201, 202, 203, 204 of the lower surface 113 of the tool head 101 on three sides of the second column of second openings 115b.

In another embodiment, the plurality of second openings 115b further include a third column of second openings 115b extending through the center of the lower surface 113 of the tool head 101, and the plurality of first openings 115a extend around the columns of second openings 115b on four sides of the columns of second openings 115b.

In another embodiment, the plurality of second openings 115b extend around a center of the lower surface 113 of the tool head 101 on four sides of the center of the lower surface 113 of the tool head 101, and the plurality of first openings 115a extend around the plurality of second openings 115b on four sides of the plurality of second openings 115b.

In another embodiment, the plurality of openings in the lower surface 113 of the tool head 101 comprise at least one third opening 115c having a third cross-section area that is greater than the first cross-section area and less than the second cross-section area.

In another embodiment, a third minimum offset distance Off₃ between the at least one third opening 115c and any peripheral edge 201, 202, 203, 204 of the lower surface 113 of the tool head 101 is greater than the first minimum offset distance Off₁ and is less than the second minimum offset distance Off₂.

In another embodiment, the second cross-section area of the at least one second opening 115b is at least two times greater than the first cross-section area of the at least one first opening 115a.

In another embodiment, the tool head includes an internal plenum 117 and a plurality of fluid conduits 116 extending between the internal plenum 117 and the plurality of openings 115a, 115b in the lower surface 113 of the tool head 101, and the die bonding tool 100 further includes a fluid conduit 119 that fluidly couples the internal plenum 117 to the vacuum source 110.

In another embodiment, the die bonding tool 100 further includes a system controller 111 coupled to the vacuum source 110 and to an actuator system, where the system controller 111 is configured to control the vacuum source 110 to generate the suction force at each of the plurality of openings 115a, 115b that are configured to temporarily secure the semiconductor die 102 against the lower surface 113 of the tool head 101, control the actuator system to align the semiconductor die 102 over a bonding region 109 of the substrate 104, control the actuator system to bring the semiconductor die 102 into contact with the bonding region 109 of the substrate 104, provide an ambient or positive pressure at the plurality of openings 115a, 115b to release the semiconductor die 102 from the lower surface 113 of the tool head 101, and control the actuator system to apply the compressive force on the semiconductor die 102 to bond the semiconductor die 102 to the substrate 104.

In one embodiment, the actuator system may be configured to move the tool head 101 to align the semiconductor die 102 over a bonding region 109 of the substrate 104, and to bring the semiconductor die 102 into contact with the bonding region 109 of the substrate 104. In another embodiment, the actuator system may be configured to move the substrate 104 to align the semiconductor die 102 over a bonding region 109 of the substrate 104, and to bring the semiconductor die 102 into contact with the bonding region 109 of the substrate 104.

Another embodiment is drawn to a tool head 101 for a die bonding tool 100 that includes a lower surface 113 having a plurality of openings 115a, 115b configured to apply a suction force to secure a semiconductor die 102 against the lower surface 113, where the plurality of openings 115a. 115b have non-uniform sizes, and a ratio of a dimension d₂ of the largest opening 115b of the plurality of openings 115a, 115b to a smallest opening 115a of the plurality of openings 115a, 115b is equal to or greater than 1.5 and less than or equal to 3.5.

In one embodiment, each of the openings 115a, 115b has a circular cross-section shape, and the dimension of each of the openings 115a, 115b is a diameter of each of the openings 115a, 115b.

In another embodiment, the diameters of each of the openings 115a, 115b are between 0.1 mm and 1.75.

In another embodiment, the smallest openings 115a are located most proximate to a periphery 201, 202, 203, 204 of the lower surface 113 and a size of the openings 115a, 115b increases towards a center of the lower surface 113.

Another embodiment is drawn to a method of bonding a semiconductor die 102 to a substrate 104 that includes securing a semiconductor die 102 to a tool head 101 for a temporary period using a suction force applied through a plurality of openings 115a, 115b in a lower surface 113 of the tool head 101, the plurality of openings 115a, 115b including at least one first opening 115a having a first cross-section area and at least one second opening 115b having a second cross-section area that is greater than the first cross-section area, and the semiconductor die 102 is secured to the tool head 101 such that a first minimum distance between the at least one first opening 115a and any peripheral edge 201, 202, 203, 204 of the semiconductor die 102 is less than a second minimum distance between the at least one second opening 115b and any peripheral edge 201, 202, 203, 204 of the semiconductor die 102, positioning the semiconductor die 102 over a bonding region 109 of a substrate 104, releasing the application of the suction force on the semiconductor die 102 such that a central region of the semiconductor die 102 contacts the bonding region 109 of the substrate 104 prior to or simultaneous with a peripheral region of the semiconductor die 10 contacting the bonding region 109 of the substrate 104, and applying a compressive force to the semiconductor die 102 to bond the semiconductor die 102 to the bonding region 109 of the substrate 104.

In one embodiment, the semiconductor die 102 is bonded to the substrate 104 using a direct bonding process.

In another embodiment, the direct bonding process is performed at room temperature.

In another embodiment, length and width dimensions L₁, L₂ of the lower surface 113 of the tool head 101 are ±10% of corresponding length and width dimensions of the semiconductor die 104.

In another embodiment, securing the semiconductor die 102 to the tool head 101 for a temporary period includes providing the semiconductor die 102 having bonding structures 106 located on an upper surface of the semiconductor die 102, securing the semiconductor die 102 to a flip tool 307 using an ejector apparatus 305, inverting the semiconductor die 102 on the flip tool 307 such that the bonding structures 106 are located on a lower surface of the semiconductor die 102, contacting the surface of the semiconductor die 102 opposite to the bonding structures 106 to the lower surface 113 of the tool head 101 to secure the semiconductor die 102 to the tool head 101, and releasing the semiconductor die 102 from the flip tool 307.

In another embodiment, positioning the semiconductor die 102 over a bonding region 109 of a substrate 104 includes moving the tool head 101 in a horizontal direction with respect to the substrate 104 to align the semiconductor die 102 over the bonding region 109 of the substrate 104, moving the tool head 101 in a vertical direction with respect to the substrate 104 to bring the semiconductor die 102 into contact with the bonding region 109 of the substrate 104 such that the bonding structures 106 on the lower surface of the semiconductor die 102 contact corresponding bonding structures 108 on the bonding region 109 of the substrate 104.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A die bonding tool, comprising:
a tool head comprising a lower surface having a plurality of openings therein; and
a vacuum source fluidly coupled to the plurality of openings in the lower surface of the tool head and configured to selectively generate a suction force at each of the plurality of openings to temporarily secure a semiconductor die against the lower surface of the tool head, wherein:
the tool head is configured to apply a compressive force on the semiconductor die to bond the semiconductor die to a substrate, and
the plurality of openings in the lower surface of the tool head comprise:
at least one first opening having a first cross-section area and a first minimum offset distance between the at least one first opening and any peripheral edge of the lower surface of the tool head; and
at least one second opening having a second cross-section area that is greater than the first cross-section area, and a second minimum offset distance between the at least one second opening and any peripheral edge of the lower surface of the tool head that is greater than the first minimum offset distance.

2. The die bonding tool of claim 1, wherein the plurality of openings in the lower surface of the tool head comprise a plurality of first openings having the first cross-section area and a plurality of second openings having the second cross-section area, wherein the first minimum offset distance between one of the plurality of first openings and any peripheral edge of the lower surface of the tool head is less than the second minimum offset distance between one of the plurality of second openings and any peripheral edge of the lower surface of the tool head.

3. The die bonding tool of claim 2, wherein the plurality of second openings are arranged in a first column of second openings and a second column of second openings located on opposite sides of a center of the lower surface of the tool head, and the plurality of first openings are disposed between the first column of second openings and a peripheral edge of the lower surface of the tool head on three sides of the first column of second openings, and wherein the plurality of first openings are disposed between the second column of second openings and a peripheral edge of the lower surface of the tool head on three sides of the second column of second openings.

4. The die bonding tool of claim 3, wherein the plurality of second openings further include a third column of second openings extending through the center of the lower surface of the tool head, and the plurality of first openings extend around the columns of second openings on four sides of the columns of second openings.

5. The die bonding tool of claim 2, wherein the plurality of second openings extend around a center of the lower surface of the tool head on four sides of the center of the lower surface of the tool head, and the plurality of first openings extend around the plurality of second openings on four sides of the plurality of second openings.

6. The die bonding tool of claim 1, wherein the plurality of openings in the lower surface of the tool head comprise at least one third opening having a third cross-section area that is greater than the first cross-section area and less than the second cross-section area.

7. The die bonding tool of claim 6, wherein a minimum offset distance between the at least one third opening and any peripheral edge of the lower surface of the tool head is greater than the first minimum offset distance and is less than the second minimum offset distance.

8. The die bonding tool of claim 1, wherein the second cross-section area of the at least one second opening is at least two times greater than the first cross-section area of the at least one first opening.

9. The die bonding tool of claim 1, wherein the tool head comprises an internal plenum and a plurality of fluid conduits extending between the internal plenum and the plurality of openings in the lower surface of the tool head, and the die bonding tool further comprises a fluid conduit that fluidly couples the internal plenum to the vacuum source.

10. The die bonding tool of claim 9, further comprising a system controller coupled to the vacuum source and to an actuator system, wherein the system controller is configured to:
control the vacuum source to generate the suction force at each of the plurality of openings that are configured to temporarily secure the semiconductor die against the lower surface of the tool head;
control the actuator system to align the semiconductor die over a bonding region of the substrate;
control the actuator system to move bring the semiconductor die into contact with the bonding region of the substrate;
provide an ambient or positive pressure at the plurality of openings to release the semiconductor die from the lower surface of the tool head; and
control the actuator system to apply the compressive force on the semiconductor die to bond the semiconductor die to the substrate.

11. The die bonding tool of claim 10, wherein the actuator system is configured to move the tool head to:
align the semiconductor die over the bonding region of the substrate; and
bring the semiconductor die into contact with bonding region of the substrate.

12. The die bonding tool of claim 10, wherein the actuator system is configured to move the substrate to:
align the semiconductor die over the bonding region of the substrate; and
bring the semiconductor die into contact with bonding region of the substrate.

13. A tool head for a die bonding tool, comprising:
a lower surface comprising a plurality of openings configured to apply a suction force to secure a semiconductor die against the lower surface, wherein the plurality of openings have non-uniform sizes, and a ratio of a dimension of the largest opening of the plurality of openings to a smallest opening of the plurality of openings is equal to or greater than 1.5 and less than or equal to 3.5.

14. The tool head of claim 13, wherein each of the openings has a circular cross- section shape, and the dimension of each of the openings comprises a diameter of each of the openings.

15. The tool head of claim 14, wherein the diameters of each of the openings are between 0.1 mm and 1.75.

16. The tool head of claim 13, wherein the smallest openings are located most proximate to a periphery of the lower surface and a size of the openings increases towards a center of the lower surface.

17. A method of bonding a semiconductor die to a substrate, comprising:
securing a semiconductor die to a tool head for a temporary period using a suction force applied through a plurality of openings in a lower surface of the tool head, wherein the plurality of openings including at least one first opening having a first cross-section area and at least one second opening having a second cross-section area that is greater than the first cross-section area, and the semiconductor die is secured to the tool head such that a first minimum distance between the at least one first opening and any peripheral edge of the semiconductor die is less than a second minimum distance between the at least one second opening and any peripheral edge of the semiconductor die;
positioning the semiconductor die over a bonding region of a substrate;
releasing the application of the suction force on the semiconductor die such that a central region of the semiconductor die contacts the bonding region of the substrate prior to or simultaneous with a peripheral region of the semiconductor die contacting the bonding region of the substrate; and
applying a compressive force to the semiconductor die to bond the semiconductor die to the bonding region of the substrate.

18. The method of claim 17, wherein the semiconductor die is bonded to the substrate using a direct bonding process.

19. The method of claim 18, wherein the direct bonding process is performed at room temperature.

20. The method of claim 17, wherein securing the semiconductor die to the tool head for the temporary period comprises:
providing the semiconductor die having bonding structures located on an upper surface of the semiconductor die;
securing the semiconductor die to a flip tool using an ejector apparatus;
inverting the semiconductor die on the flip tool such that the bonding structures are located on a lower surface of the semiconductor die;
contacting the surface of the semiconductor die opposite to the bonding structures to the lower surface of the tool head to secure the semiconductor die to the tool head; and
releasing the semiconductor die from the flip tool.
